(19) United States
(12) Patent Application Publication
(10) Pub. No.: US 2015/0295120 A1
(43) Pub. Date: Oct. 15, 2015

(54) OPTICAL COUPLING DEVICE

(71) Applicant: KABUSHIKI KAISHA TOSHIBA, Tokyo (JP)

(72) Inventors: Satoshi KOMOTO, Fukuoka (JP); Tatsuhiko NAGAFUCHI, Fukuoka (JP); Yuta KUGIYAMA, Fukuoka (JP)

(21) Appl. No.: 14/748,678

(22) Filed: Jun. 24, 2015

Related U.S. Application Data
(62) Division of application No. 13/605,776, filed on Sep. 6, 2012.

(30) Foreign Application Priority Data
Feb. 24, 2012 (JP) 2012-038650

(51) Int. Cl. H01L 31/167; G01J 1/42; G01J 1/02

(52) U.S. Cl. CPC H01L 31/167; G01J 1/0209; G01J 1/42

(57) ABSTRACT

An optical coupling device includes a first lead part, a light emitting element mounted on the first lead part, a first wire connected to the first lead part and the light emitting element, a second lead part, a light receiving element fixed to the second lead part, a second wire connected to the second lead part and the light receiving element, and an insulating film configured to allow passage of light emitted from the light emitting element. The insulating film does not make contact with the first lead part, the light emitting element, the first wire, the second lead part, the light receiving element, or the second wire.

### CROSS-REFERENCE TO RELATED APPLICATION

This application is a division of U.S. patent application Ser. No. 13/605,776, filed on Sep. 6, 2012, which is based upon and claims the benefit of priority from Japanese Patent Application No. 2012-038650, filed Feb. 24, 2012; the entire contents of which are incorporated herein by reference.

### FIELD

Embodiments described herein relate to an optical coupling device.

### BACKGROUND

A photocoupler contains a light emitting element and a light receiving element and has primary and secondary zones which are electrically insulated from each other. An optical signal propagates through the optical coupler, with the propagation enabled by optical coupling. There are various applications of the photocoupler that require a high insulating voltage rating of, e.g., a few kV. Also, the light emitting element and the light receiving element of the photocoupler may be covered by a monolithic transparent resin body, and the periphery of the photocoupler may be molded with a light blocking resin material. In general, in order to increase the voltage insulation rating, an insulating film that is transparent may be inserted into the transparent resin material. Such insertion may not be sufficient, because in general a photocoupler requires higher voltage insulation ratings.

### DESCRIPTION OF THE DRAWINGS

FIG. 1A is a perspective view of an optical coupling device according to a first embodiment. FIG. 1B is a cross-sectional view taken across A-A′ in FIG. 1A.

FIG. 2A is a perspective view illustrating a jig for manufacturing the optical coupling device of the first embodiment. FIG. 2B is a cross-sectional view taken across B-B′ in FIG. 1A.

FIG. 3 is a plane view illustrating operations associated with the manufacturing method of the optical coupling device of the first embodiment.

FIG. 4A is a plane view illustrating operations associated with the manufacturing method of the optical coupling device of the first embodiment. FIG. 4B is a cross-sectional view illustrating the operations.

FIGS. 5A through 5C are cross-sectional views illustrating operations associated with an example of the manufacturing method of the optical coupling device of the first embodiment.

FIGS. 6A and 6B are cross-sectional views illustrating the operations of the example of the manufacturing method of the optical coupling device of the first embodiment.

FIGS. 7A through 7E are side views illustrating the operations associated with the manufacturing method of an optical coupling device of a comparative example.

FIG. 8 is a cross-sectional view illustrating an example of the optical coupling device of the comparative example.

FIG. 9 is a cross-sectional view illustrating an example of the optical coupling device according to a second embodiment.

FIG. 10 is a cross-sectional view illustrating the operation in an example of the manufacturing method of the optical coupling device of the second embodiment.

FIG. 11 is a plane view illustrating an example of the positional relationship between the lead part and the insulating film in the optical coupling device according to a third embodiment.

FIG. 12 is a plane view illustrating an example of the positional relationship between the lead part and the insulating film in the optical coupling device according to a fourth embodiment.

### DETAILED DESCRIPTION

In general, embodiments of the optical coupling device will be explained with reference to the attached drawings.

According to a first embodiment, there is provided an optical coupling device with a high insulating voltage rating.

The optical coupling device according to the embodiment has a first lead part, a light emitting element mounted on the first lead part, a first wire connected to the first lead part and the light emitting element, a second lead part, a light receiving element fixed to the second lead part, a second wire connected to the second lead part and the light receiving element, and an insulating film configured to allow passage of light emitted from the light emitting element. The insulating film does not make contact with the first lead part, the light emitting element, the first wire, the second lead part, the light receiving element, or the second wire.

First of all, Embodiment 1 will be explained.

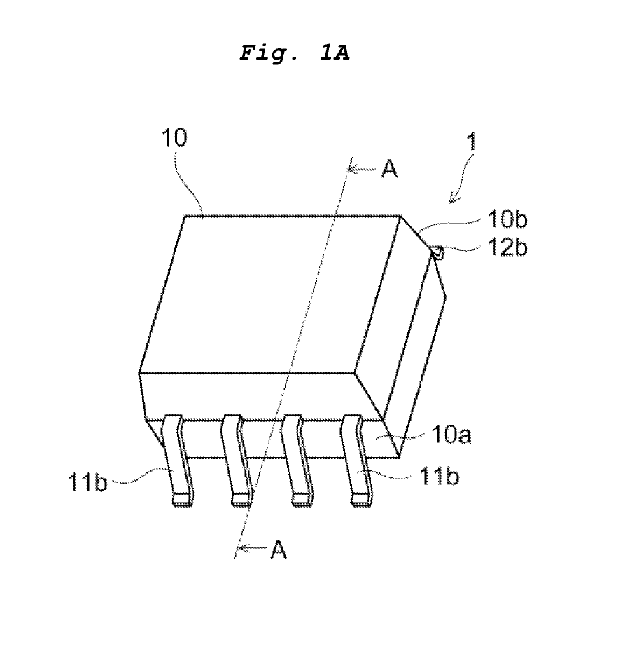

FIG. 1A is a perspective view illustrating an example of the optical coupling device of the present embodiment. FIG. 1B is a cross-sectional view taken across A-A′ in FIG. 1A.

The optical coupling device of the present embodiment is a photocoupler.

As shown in FIG. 1A, for the optical coupling device 1 of this embodiment, a molding 10 made of a resin forms an outer layer thereof. At one side surface 10a of the molding 10, several (e.g., 4) leads 11b are arranged. The leads protrude outwards and are bent downwards. At the side surface 10b on the side opposite to the side surface 10a, several (e.g., 4) leads 12b (only one of which is shown in part) are arranged. The leads protrude outwards and are bent downwards.

The lead parts 11 and 12 are arranged in the optical coupling device 1 as shown in FIG. 1B. The lead part 11 and the lead part 12 are displaced from each other. Lead part 11 comprises a plate-shaped mount bed 11a and multiple leads 11b. The mount bed 11a and one lead 11b are integrated. Lead part 12, too, comprises a plate-shaped mount bed 12a and leads 12b. The mount bed 12a is integrated with one of the leads 12b. The leads 11b and 12b are arranged at the same height. The mount bed 11a lies below an upper portion of the leads 11b, and the mount bed 12a lies above the leads 12b. As a result, the mount bed 12a lies directly above the mount bed 11a but is displaced from it. In addition, the mount beds 11a and 12a are parallel to each other.

The upper surface of the mount bed 11a holds a die mount 13 on which the light emitting element 14 is mounted. The light emitting element 14 is a chip containing an LED (light emitting diode) which emits IR light or visible light as electric power is fed to it. The various terminals of the light emitting element 14 are connected to the leads 11b via wires 15.

The lower surface of the mount bed 12a of the lead part 12 holds a die mount 16 with a light receiving element 17 fixed to its underside. Here, the light receiving element 17 may be a chip containing a PD (photodiode) which receives IR light or visible light and converts it into an electric signal. The various terminals of the light receiving element 17 are connected to the leads 12b via wires 18.

The die mounts 13 and 16 may be formed from an electroconductive epoxy resin. The wires 15 and wires 18 are made of, e.g., gold. For convenience of illustration, in FIG. 1B, only one of the wires 15 and one of the wires 18 is shown. The same is true for the other figures displaying cross-sectional views.

The mount bed 11a and the mount bed 12a are arranged so as to face each other. The light emitting element 14 on the upper surface of the mount bed 11a and the light receiving element 17 on the lower surface of the mount bed 12a also face each other. Consequently, the light emitting element 14 and light receiving element 17 are positioned so that light emitted from the light emitting element 14 is incident on the light receiving element 17.

On the upper surface of the mount bed 11a, a transparent resin body 21 is arranged. The transparent resin body 21 is formed from an insulating transparent resin that allows light emitted from the light emitting element 14. It is in contact with a portion of the upper surface of the mount bed 11a, and covers the die mount member 13 and light emitting element 14 entirely as well as at least a portion of the wires 15. On the other hand, the lower surface of the mount bed 12a is in contact with a transparent resin body 22. Here, the transparent resin body 22 is also formed from an insulating transparent resin that allows transmission of light emitted from the light emitting element 14. The transparent resin body 22 is in contact with a portion of the lower surface of the mount bed 12a, and it covers the die mount 16 and the light receiving element 17 entirely, and at least a portion of the wires 18. The transparent resin for forming the transparent resin body 21 and transparent resin body 22 may be a thermosetting or UV setting resin. The transparent resin forming the transparent resin body 21 and the transparent resin forming the transparent resin body 22 may be formed from different resins, respectively.

An insulating film 23 lies between the transparent resin body 21 and the transparent resin body 22. The insulating film 23 also includes an insulating transparent resin that allows transmission of the light emitted from the light emitting element 14. In one embodiment, the shape of the insulating film 23 is a rectangular sheet. The insulating film 23 is in contact with the transparent resin body 21 and the transparent resin body 22, and the transparent resin body 21 and the transparent resin body 22 are separated from each other by the insulating film 23. That is, the entire circumference of the outer peripheral portion of the insulating film 23 protrudes out from the transparent resin body 21 and transparent resin body 22. Consequently, the transparent resin body 21 does not make direct contact with the transparent resin body 22.

The insulating film 23 is not in contact with the leads 11 and 12, the die mounts 13 and 16, the light emitting element 14, the light receiving element 17, or the wires 15 and 18. In one example, the insulating film 23 may be arranged to be parallel with the mount beds 11a and 12a be positioned equidistant from the mount beds 11a and 12a.

The shapes of the transparent resin bodies 21 and 22 are tapered so that they are wider towards the insulating film 23. That is, the horizontal cross-sectional area of the contact region 21a where the transparent resin body 21 contacts the insulating film 23 is larger than the horizontal cross-sectional area of the region surrounded by the outer edge of the contact region 21b where the transparent resin body 21 contacts the mount bed 11a. Also, the horizontal cross-sectional area of the contact region 22a where the transparent resin body 22 contacts the insulating film 23 is larger than the horizontal cross-sectional area of the region surrounded by the outer edge of the contact region 22b where the transparent resin body 22 contacts the mount bed 12a. Here, the “region surrounded by the outer edge of the contact region 21b where the transparent resin body 21 contacts the mount bed 11a” refers to the region on the upper surface of the mount bed 11a, including not only the region in contact with the transparent resin body 21 but also the region in contact with the die mount 13 and wires 15, since these components are covered by the transparent resin body 21.

Also, a light blocking resin body 25 is disposed in the optical coupling device 1. Here, the light blocking resin body 25 is formed of a light blocking resin that blocks the light emitted from the light emitting element 14 that may otherwise be received by the light receiving element 17, such as a black resin or a white resin. The light blocking resin body 25 completely covers the transparent resin bodies 21 and 22, insulating film 23, and mount beds 11a and 12a, and it covers the portion of the leads 11b on the side of the mount bed 11a and a portion of the leads 12b located to the side of the mount bed 12a. The components arranged in the transparent resin bodies 21 and 22, such as the light emitting element 14 and light receiving element 17, are enclosed within the light blocking resin body 25. Also, any portions of the wires 15 and 18 not covered by the transparent resin bodies 21 and 22 are surrounded by the light blocking resin body 25. As a result, the light blocking resin body 25 forms the outer layer of the molding 10. On the other hand, the portion of the leads 11b on a side remote from the mount bed 11a and the portion of the leads 12b on a side remote from the mount bed 12a protrude out from the light blocking resin body 25. Consequently, they also protrude out from the molding 10.

In the following, the manufacturing method of the optical coupling device related to the present embodiment will be explained.

First of all, the jig used to manufacture the optical coupling device related to the present embodiment will be explained.

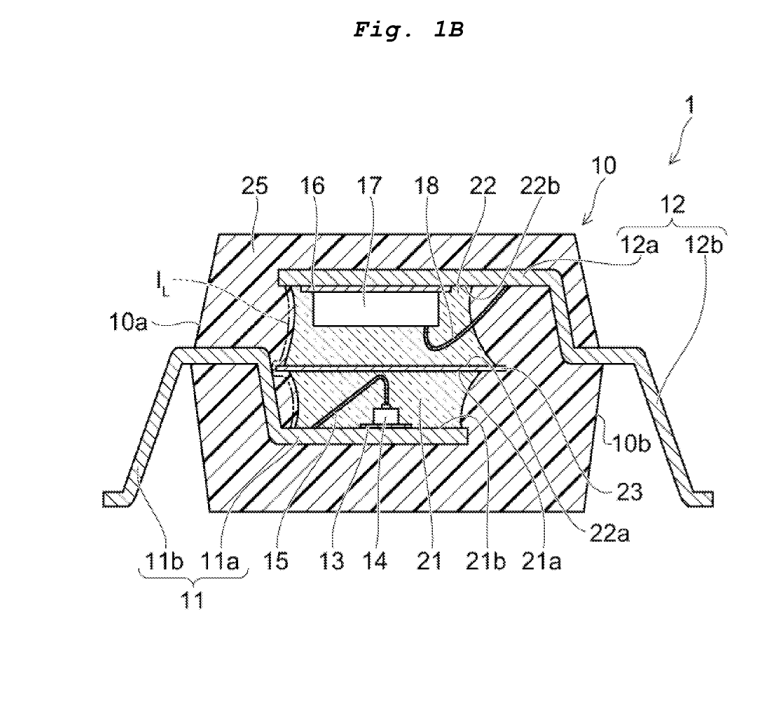

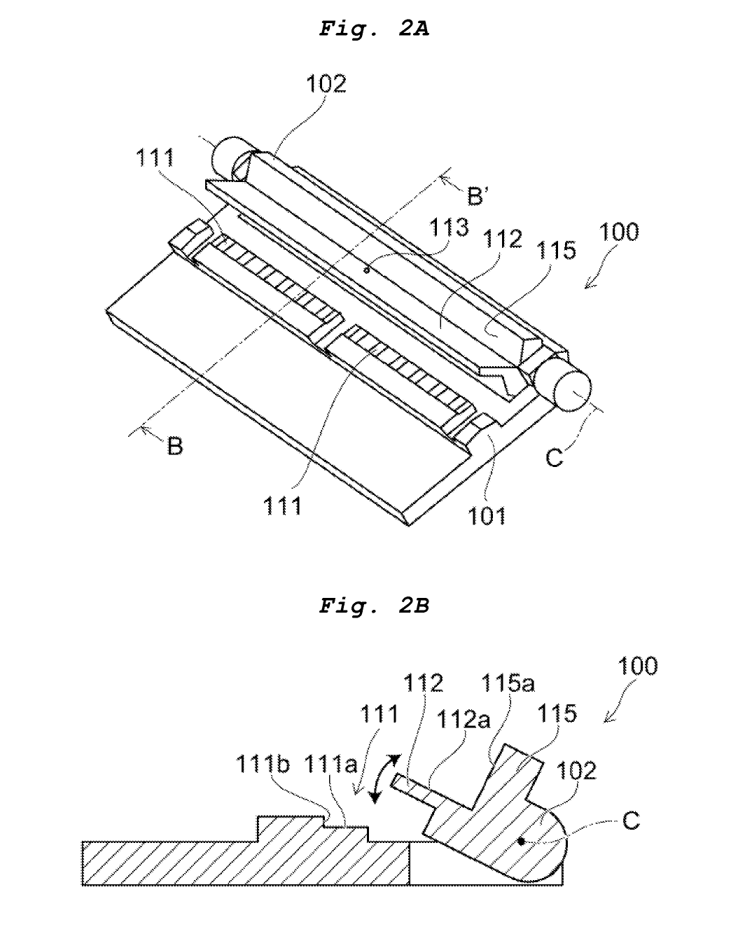

FIG. 2A is a perspective view illustrating an example of the jig used to manufacture the optical coupling device of the present embodiment. FIG. 2B is a cross-sectional view taken across B-B′ in FIG. 2A.

Jig 100 shown in FIGS. 2A and 2B is used to fabricate the optical coupling device in the present embodiment. The jig 100 has a base 101 and a movable part 102. The end portion of the base part 101 and the end portion of the moving part 102 form a hinged mechanism. The movable part 102 is connected to the base part 101 so that it can pivot around a rotating shaft C which serves as a hub. The base part 101 and movable part 102 each have mostly a plate shape.

In the lengthwise direction of the rotating shaft C, the dimensions of the base part 101 and the movable part 102 are approximately equal to each other. On the other hand, in a direction perpendicular to the axis of rotating shaft C, the movable part 102 is shorter than the base part 101. As a result, when the side of the movable part 102 facing the base part 101 is positioned at the end of its rotating region, the movable part 102 covers only a portion of the upper surface of the base part 101. As it completes its range of motion, movable part 102 is brought into contact with part of the base portion 101.

Several pockets 111 are formed on the upper surface of the base part 101 to the outside of the rotating region of the movable part 102. The pockets 111 are arranged in a row running in the lengthwise direction of the rotating shaft C. Each pocket 111 has a partially concave shape. That is, each pocket 111 has a flat rectangular bottom 111a. One edge of the bottom 111a facing the rotating shaft C is open, and the remaining three edges form a side wall 111b. The shape and size of the bottom 111a are similar to the shape and size of the insulating film 23. Consequently, the insulating film 23 in the pockets 111 is held so that its movement in the three directions is restrained by the side wall 111b, keeping it anchored in position with respect to the base part 101.

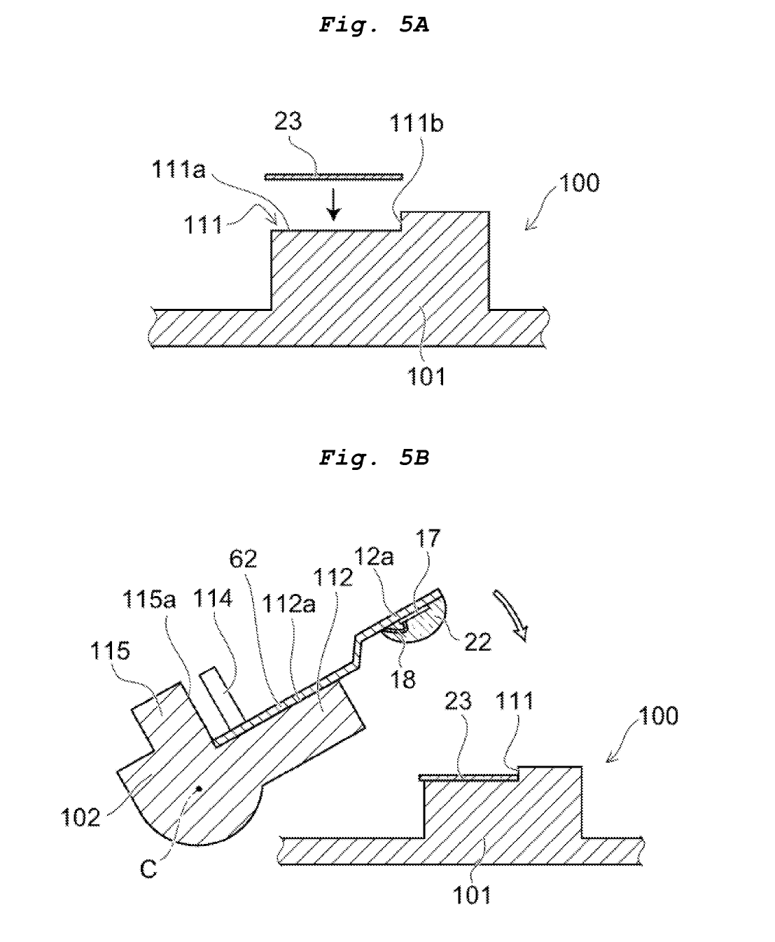

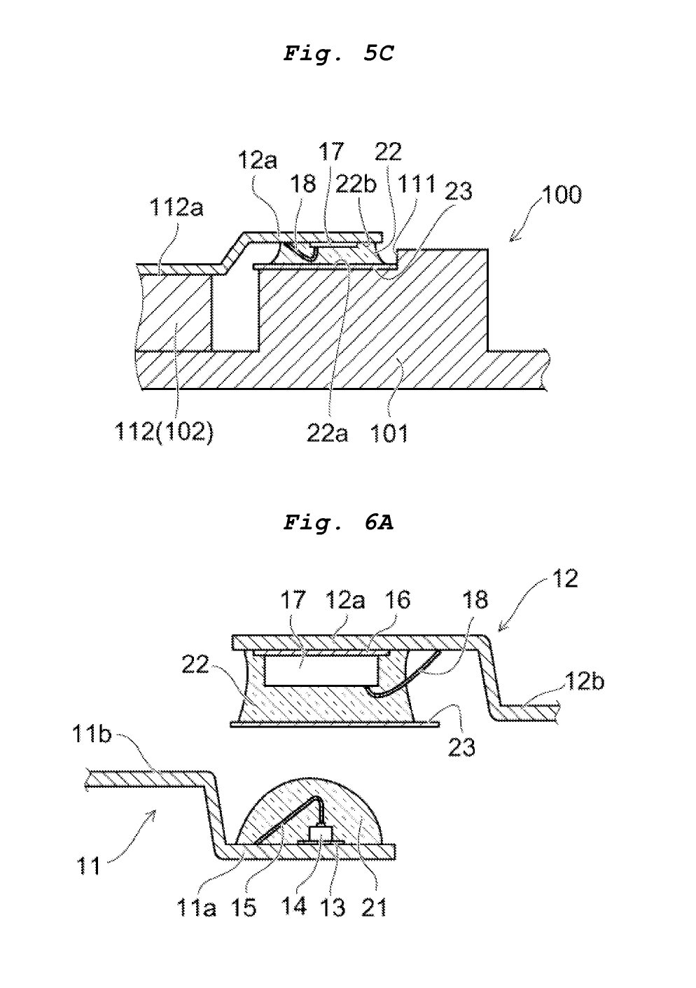

On the other hand, a plate part 112 is contained in the movable part 102. The upper surface 112a of the plate 112 is flat, and one or more holes 113 may be formed in the upper surface 112a. A positioning pin 114 (see FIG. 5B) fits in one of the holes 113. In addition, the plate part 112 has a restrainer 115, and the side surface 115a of the restrainer 115 is perpendicular to the upper surface 112a of the plate 112. As a result, the upper surface 112a of the plate 112 toward the direction of the rotating shaft C terminates at the position 115a of the restrainer 115. On the other hand, the side opposite the rotating shaft C is open, so that when the moving part 102 is at the end of its excursion facing the base part 101, the top 112a of the plate 112 is parallel with the bottom 111a of the pockets 111.

In the following, the manufacturing method of the optical coupling device using the jig 100 will be explained.

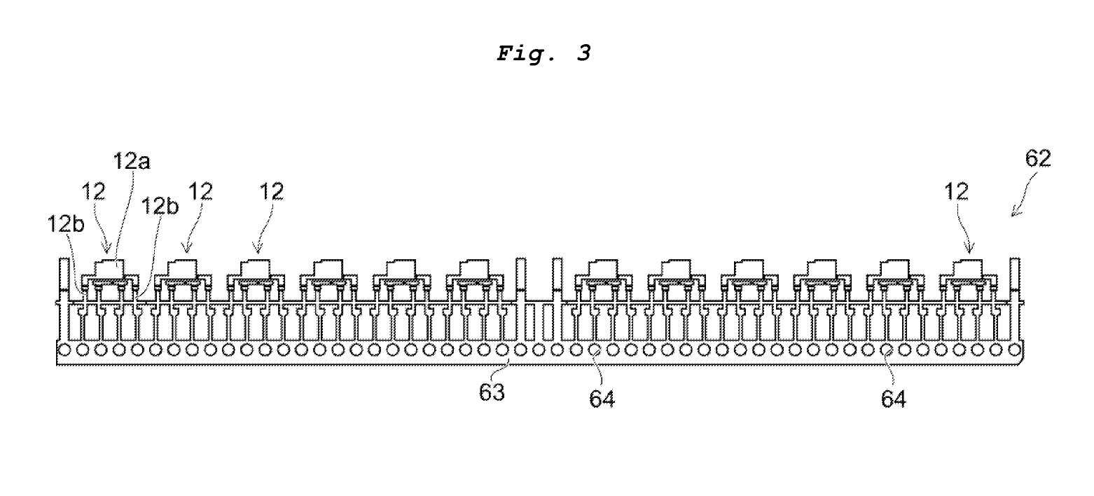

FIG. 3 is a plane view illustrating the method used to fabricate the optical coupling device of the present embodiment.

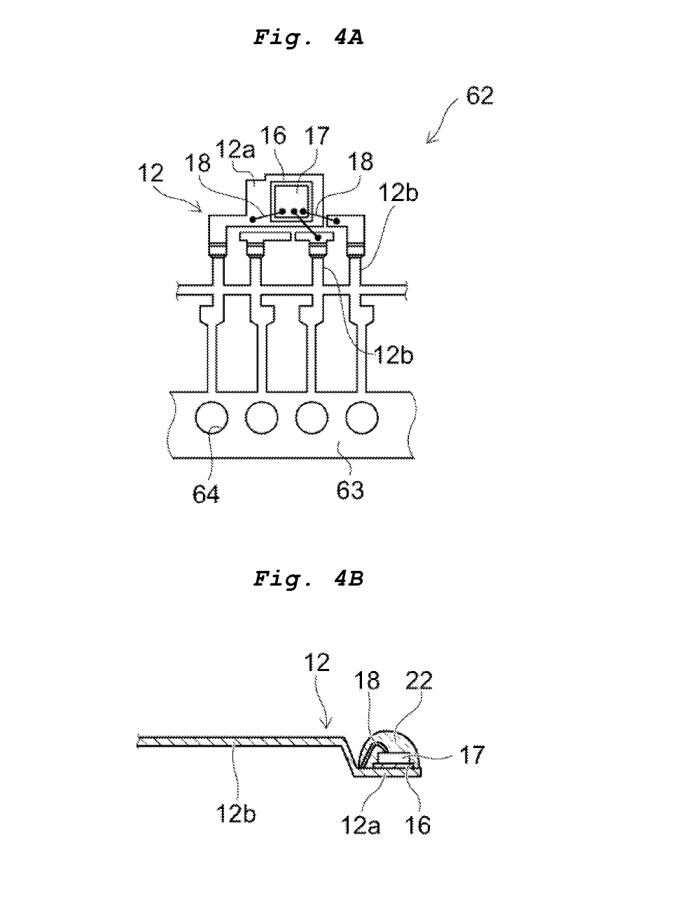

FIG. 4A is a plane view illustrating the method used to fabricate the optical coupling device of the present embodiment, and FIG. 4B is a cross-sectional view.

FIGS. 5A through 5C are cross-sectional views illustrating an example of a method used to fabricate the optical coupling device of the present embodiment.

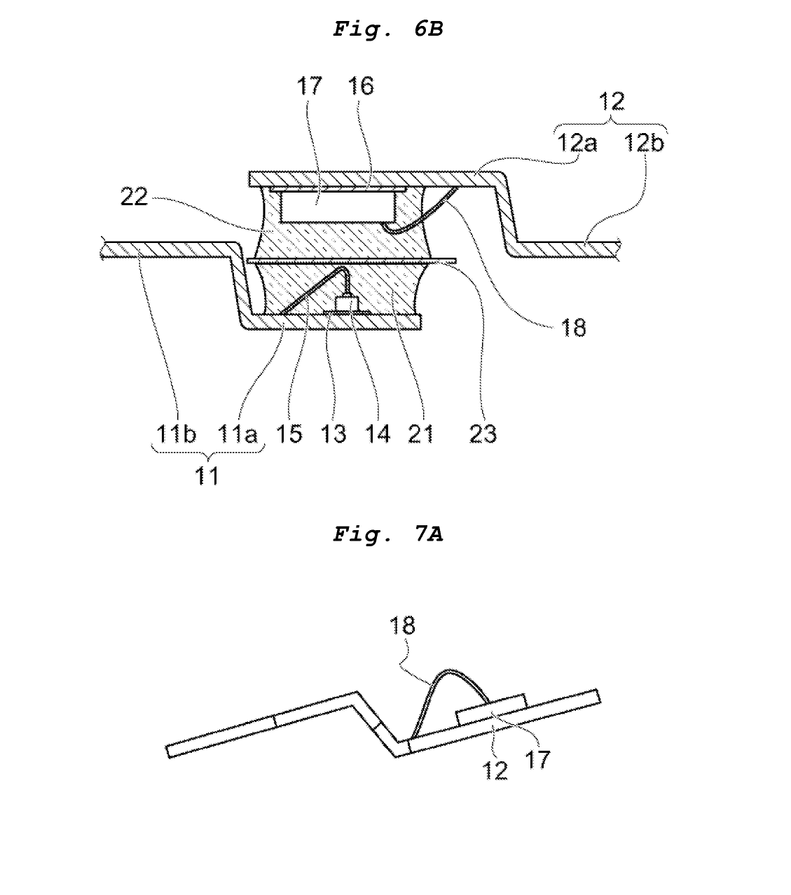

FIGS. 6A and 6B are cross-sectional views illustrating an example of a method used to fabricate the optical coupling device of the present embodiment.

First of all, as shown in FIG. 3, a lead frame 62 is prepared. As part of the lead frame 62, a ribbon-shaped frame 63 extending unidirectionally is arranged. On one side of the ribbon-shaped frame 63, several lead parts 12 are connected. The lead parts 12 and frame 63 form a unified structure, and the lead parts 12 are laid out along the length of the frame 63. A row of holes 64 in the frame 63 extends along its length. Among the various lead parts 12, leads 12b are fixed to the frame 63, and the mount bed 12a lies on the side of the lead parts 12 opposite the frame 63.

Then, as shown in FIG. 4A, the die mount 16 is installed on the mount bed 12a in the lead frame 62. A light receiving element 17 is then mounted on the die mount 16. Next, the terminals of the light receiving element 17 are connected, via wires 18, to the leads 12b. In the example shown in FIG. 4A, the ground, power supply and signal terminals of the light receiving element 17 are connected to three different leads 12b via the wires 18, and the remaining one lead 12b is not used.

Then, as shown in FIG. 4B, a transparent resin (epoxy resin) is coated on each mount bed 12a. This forms the transparent resin body 22 that covers the die mount member 16, light receiving element 17 and wires 18. However, at this stage the transparent resin body 22 is not yet cured and is in semi-liquid form.

Similarly, a lead frame that combines several lead parts 11 is prepared, and the die mount 13 is disposed on the mount bed 11a of each lead part 11. In this way, the die mount 13 supports the light emitting element 14. Next, the wires 15 are bonded and the various terminals of the light emitting element 14 are connected to the leads 11b via the wires 15. The transparent resin (epoxy resin) is then coated on the mount bed 11a, and the resulting transparent resin body 21 covers the die mount member 13, light emitting element 14 and wires 15. At this stage the transparent resin body 21 is not cured, and it is in semi-liquid form.

Then, the moving part 102 of the jig 100 is pivoted to the end on a side that is remote from the base 101, and as shown in FIG. 5A, an insulating film 23 is applied to each of the pockets 111 of the base 101. The insulating film 23 coats the bottom 111a of the pockets 111 and adjoins the side wall 111b. The insulating film 23 is thereby positioned with respect to the base 101.

Then, as shown in FIG. 5B, the lead frame 62 is placed on the upper surface 112a of the plate 112 of the movable part 102. The lead frame 62 is positioned so that it abuts the side 115a of the restraining part 115. In this configuration, the surface of the lead frame 62 which is covered with the transparent resin body 22 faces downward. The one or more positioning pins 114 are then each inserted through one of the holes 64 on the lead frame 62 and through one of the holes 113 in the plate part 112 to hold the lead frame 62 positioned with respect to the moving part 102, which is then pivoted towards the base part 101.

As a result, as shown in FIG. 5C, the mount bed 12a of the lead frame 62 is positioned directly above the insulating film 23. The mount bed 12a lies at a prescribed distance from the insulating film 23 and is parallel to the insulating film. As a result, the transparent resin body 22, in semi-liquid form on the mount bed 12a, is deformed so that it presses on the insulating film 23. The distance between the insulating film 23 and the mount bed 12a is set so that the insulating film 23 does not contact the light receiving element 17 and the wires 18.

As a result, the transparent resin body 22 contacts both the mount bed 12a and the insulating film 23 and, due to surface tension, the transparent resin body 22 is pulled onto both the mount bed 12a and the insulating film 23. The motion as a whole is, however, downward towards the side of the insulating film 23 under the force of gravity. As a result, the sides of the transparent resin body 22 have a concave curvature and its cross-section near the insulating film 23 is wider than near the mount bed 12a. As a result, the area of the contact region 22a where the transparent resin body 22 contacts the insulating film 23 is larger than the area of the region surrounded by the outer edge of the contact region 22b where the transparent resin body 22 contacts the mount bed 12a. In this state, by heating or irradiation of UV light, the transparent resin body 22 is cured. For example, for each jig 100, the leads 12, the transparent resin body 22 and the insulating film 23 are placed in a thermostatically controlled vessel kept at a temperature in the range of 100 to 150° C. As a result, the transparent resin body 22 is cured and the insulating film 23 is bonded to the transparent resin body 22.

Then, as shown in FIG. 6A, the lead frame on the light emitting element side (not shown in the figure) and the lead frame 62 on the light receiving element side are combined.

As shown in FIG. 6B, the resulting transparent resin body 22 on which the insulating film 23 is bonded is moved towards the semi-liquid transparent resin body 21 which has been formed over the light emitting element 14 and which covers the leads 11. As a result, the transparent resin body 21 is pressed against and attached to the insulating film 23. The resulting transparent resin body 21 is pulled towards and attaches to both the mount bed 11a and the insulating film 23. The sides of the resin body 21 form a concave curvature. In this manner, by using a jig to anchor the two lead frames so as to maintain a relative position of the mount bed 11a and the mount bed 12a, the relative position of the insulating film 23 with respect to the mount bed 11a can be maintained. Also, the insulating film 23 is prevented from contacting the leads 11, light emitting element 14, and wires 15.

In this case, because the transparent resin body 21 lies above the insulating film 23, the semi-liquid transparent resin body 21 flows towards the insulating film 23 under the force of gravity. As a result, the transparent resin body 21 acquires its concavely curved sides. At the same time, the lower portion of the resin body 21, that is, the portion nearer to the insulating film 23, becomes wider than the upper portion near the mount bed 11a. That is, the area of the contact region 21a (see FIGS. 1A and 1B) where the transparent resin body 21 contacts the insulating film 23 is larger than the area of the region surrounded by the outer edge of the contact region 21b (see FIGS. 1A and 1B) where the transparent resin body 21 contacts the mount bed 11a.

Subsequently, heating or UV irradiation is used to cure the transparent resin body 21 and bond the insulating film 23 to it. The lead parts 11 and 12 then become bonded with each other via the transparent resin body 21, insulating film 23 and transparent resin body 22.

Then, as shown in FIGS. 1A and 1B, a light blocking resin body 25 made of a black resin or a white resin is formed and cured in a position in which it encapsulates the entire transparent resin body 21, insulating film 23, transparent resin body 22, mount bed 11a and mount bed 12a, as well as a portion of the leads 11b and 12b. This step forms the molding 10. Su Subsequently, the leads 11b are separated from the frame 63 of the lead frame 62 on the light emitting side (not shown in the figure), and the leads 12b are separated from the frame 63 (see FIG. 3) of the lead frame 62 on the light receiving side. As a result, each molding 10 is formed individually for each of the lead parts 11 and 12 that it covers. The leads 11b and 12b which protrude beyond the outer side of the molding 10 are then folded and bent downwards, and the optical coupling device 1 is complete.

In the following, the operation and effects of the present embodiment will be explained.

According to the present embodiment, the jig 100 is used to bring the insulating film 23 into contact with the transparent resin body 22, so that the position of the insulating film 23 with respect to the lead parts 12 is maintained. Also, by fixing the relative positions of the lead parts 11 and 12, one can fix the position of the insulating film 23 with respect to the lead parts 11 and 12. Therefore, the insulating film 23 can be disposed so that it does not contact the lead parts 11 and 12, the light emitting element 14, the light receiving element 17, or the wires 15 and 18. Also, the insulating film 23 can be positioned so that the transparent resin bodies 21 and 22 are displaced from each other, thereby providing a distance I_{L} (see FIG. 1B) along the surface between the lead parts 11 and 12. This distance allows the voltage rating between the lead parts 11 and 12 to be increased.

Also, because the insulating film 23 does not contact the wires 15 and 18, the insulating film 23 does not apply a mechanical stress on the wires 15 and 18. Thus, deformation or breakage of the wires 15 and 18 can be avoided during fabrication and use of the optical coupling device 1. Also, because the insulating film 23 also does not contact the light emitting element 14 and light receiving element 17, it does not apply a mechanical stress on these elements. These elements are consequently spared the damage that would otherwise result from such stress, and which leads to surge breakage of the semiconductor joint portion. As a result, the optical coupling device 1 of this embodiment is more reliable.

In addition, according to this embodiment, it is possible to control the position of the insulating film 23 with respect to the lead parts 11 and 12 more precisely. Consequently, spreading of the transparent resin bodies 21 and 22 is avoided, and the voltage rating is stable. Also, because the portion of the insulating film 23 that is surrounded by the light blocking resin body 25 is constant, the strength of the light blocking resin body 25 is also stable.

In addition, according to the present embodiment, the insulating film 23 is arranged parallel to the mount bed 11a and the mount bed 12a. This decreases the variation of the distance to the mount bed 11a, 12a along the surface of the insulating film 23 and makes the voltage rating more stable.

In addition, for the optical coupling device 1 related to the present embodiment, the transparent resin bodies 21 and 22 have tapered sides such that the end facing the insulating film 23 is wider than the opposite end. As a result, there is less overlap of the optical paths from the light emitting element 14 to the light receiving element 17 In this way the light utilization efficiency is improved. In other words, most of the light emitted from the light emitting element 14 can reach the insulating film 23 after being transmitted into the tapered transparent resin body 21 without being significantly blocked by the light blocking resin body 25. Most of the light scattered by the insulating film 23 can then be transmitted in the transparent resin body 22 in a shape that narrows towards the light receiving element 17. As a result, the light can reach the light receiving element 17 without being blocked by the light blocking resin body 25.

In the following discussion we consider some examples for comparison.

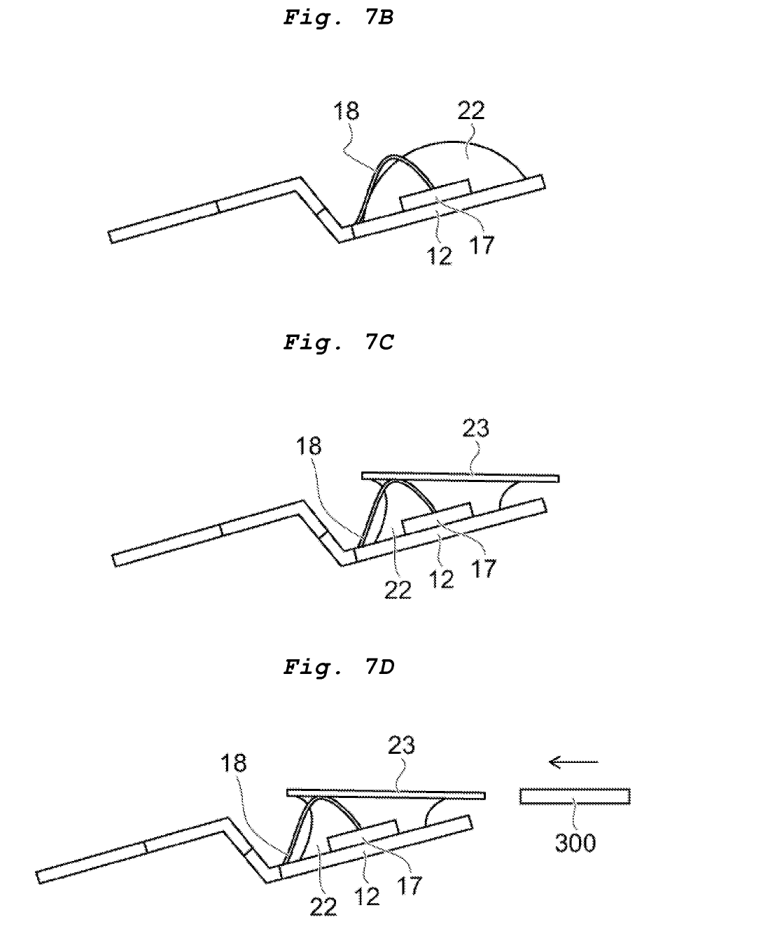

FIGS. 7A through 7E are side views illustrating a method for fabricating the optical coupling device of a comparative example.

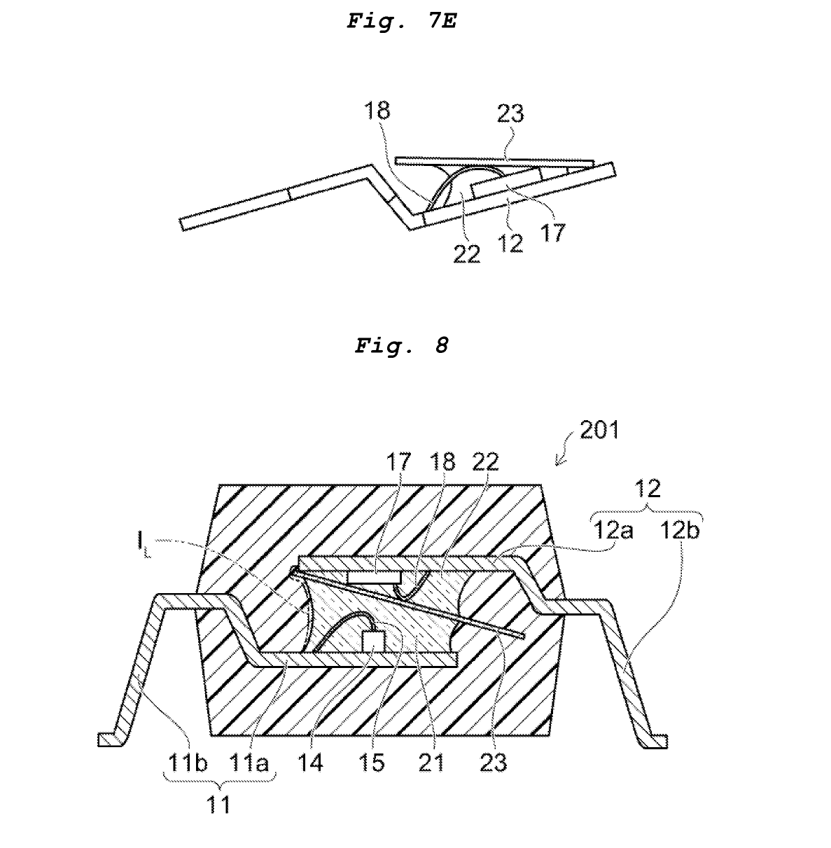

FIG. 8 is a cross-sectional view illustrating an example of the optical coupling device related to the comparative example.

First of all, the method used to fabricate the optical coupling device of a comparative example will be explained.

As shown in FIG. 7A, the die mount 16 (see FIG. 1B) and light receiving element 17 are mounted on the lead parts 12 of the lead frame 62 (see FIG. 3), and the wires 18 are bonded.

Then, as shown in FIG. 7B, the transparent resin body 22 is applied in a semi-liquid state to cover the light receiving element 17.

As shown in FIG. 7C, the insulating film 23 is then placed on the transparent resin body 22. In this case, as the transparent resin body 22 is in a semi-liquid state, the insulating film 23 rides on and is supported by the wires 18. Also, the surface tension between the transparent resin body 22 and the insulating film 23 deforms the transparent resin body, which is sucked up towards, and attached to, the insulating film 23.

Then if needed, the end portion of the insulating film 23 is made to bulge by a jig 300, so that the position of the insulating film 23 is adjusted by a certain degree as shown in FIG. 7D. However, in this case, once the insulating film 23 contacts the wires 18, it can only be separated from them with difficulty. On the other hand, when the insulating film 23 comes into contact with the light receiving element 17, mount bed 12a, and other components, the position may become fixed.

Then, as shown in FIG. 7E, the transparent resin body 22 is cured.

Then, as shown in FIG. 8, the insulating film 23 bonded with the lead parts 12 via the transparent resin body 22 is brought into contact with the transparent resin body 21 covering the lead parts 11. Then, the transparent resin body 21 is cured, after which the light blocking resin body 25 is formed. In this way, the optical coupling device 201 of the present comparative example is manufactured.

In the present comparative example, the insulating film 23 is not precisely positioned, so that the insulating film 23 may contact the mount bed, the elements, the wires, etc., thereby causing the voltage rating between the lead parts 11 and the lead parts 12 to vary. For example, in the example shown in FIG. 8, when the insulating film 23 contacts the mount bed 12a, the distance I_{L} along the smaller surface of the transparent resin 22 is shortened. Consequently, the voltage rating between the lead parts 11 and 12 decreases.

Also, in the manufacturing step shown in FIG. 7C, the insulating film 23 rides on the wires 18 which support it. However, when the insulating film 23 makes contact with the wires, it exerts a mechanical stress on them which may easily cause deformation, damage, breaking, etc. of the wires, and resulting electrical failure. Also, when the insulating film 23 contacts the light emitting element 14 or light receiving element 17, the elements may be mechanically damaged, the insulating voltage rating may be decreased, or surge breakdown of the semiconductor joint portion may occur. This degrades the performance of the optical coupling device 201 of the present comparative example.

In the manufacturing process of the comparative example, the position of the insulating film 23 cannot be controlled with high precision. Consequently, in the manufacturing process of the optical coupling device 201, deviations in the position and angle of the insulating film 23 occur easily. As a result, after molding of the light blocking resin body 25, cracks and decreased strength of the light blocking resin body 25 may result, thereby reducing the reliability of the optical coupling device 201.

In the following, Embodiment 2 will be explained.

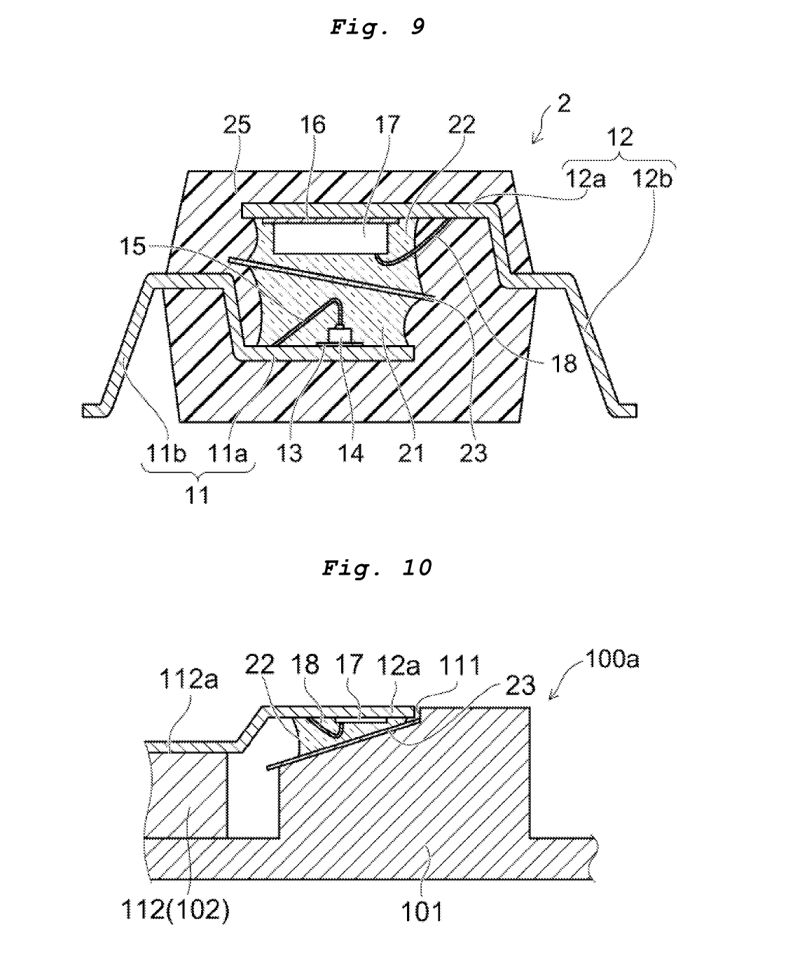

FIG. 9 is a cross-sectional view illustrating an example of an optical coupling device of the present embodiment.

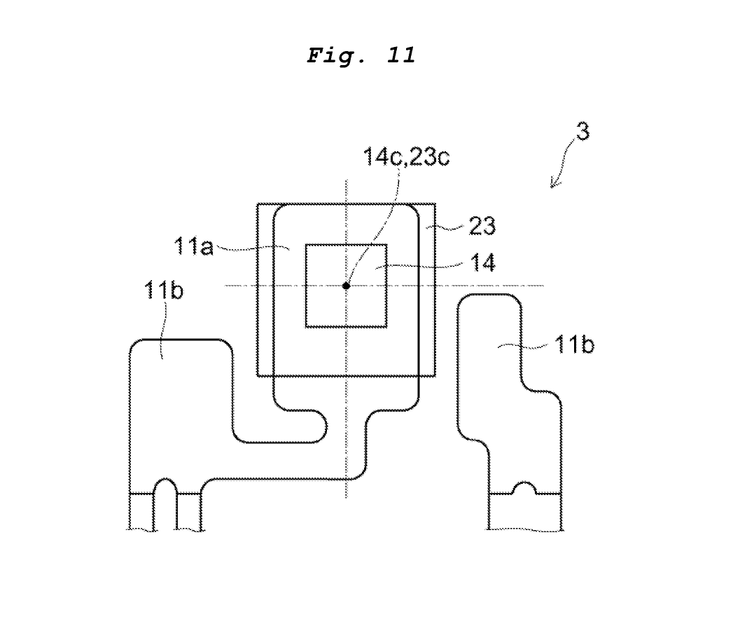

FIG. 10 is a cross-sectional view illustrating an example of a method used to fabricate the optical coupling device of the present embodiment.

As shown in FIG. 9, the optical coupling device 2 in the present embodiment differs from the device 1 of Embodiment 1 (see FIG. 1B) in that the insulating film 23 is angled so as to not be parallel to the mount beds 11a and 12a. Otherwise, the present embodiment is identical to Embodiment 1. For example, in the present embodiment, the insulating film 23 does not contact the lead parts 11 and 12, the light emitting element 14, the light receiving element 17, or the wires 15 and 18. Also, the transparent resin bodies 21 and 22 are separated from each other by the insulating film 23.

As shown in FIG. 10, the optical coupling device 2 of the present embodiment can be manufactured by using a jig 100a in which the bottom surface 111a of the pocket 111 of the base part 101 is inclined relative to the plate 112 of the moving part 102. That is, instead of the step shown in FIG. 5C in Embodiment 1, the step shown in FIG. 10 is performed, so that the transparent resin body 22 is cured while the position of the insulating film 23 is kept inclined relative to the mount bed 12a. Then, as shown in FIG. 6A, while the mount bed 11a is kept parallel to the mount bed 12a, the transparent resin body 21 is brought in contact with the insulating film 23, and the transparent resin body 21 is cured. Thus, in accordance with the present embodiment, the manufacturing method is the same as in Embodiment 1, with the exception of the inclination of insulating film 23. According to the present embodiment, the same operations and effects as those of the Embodiment 1 can be realized.

In the following, Embodiment 3 will be explained.

FIG. 11 is a plane view illustrating an example of the positional relationship between the leads and the insulating film in the optical coupling device used in the present embodiment.

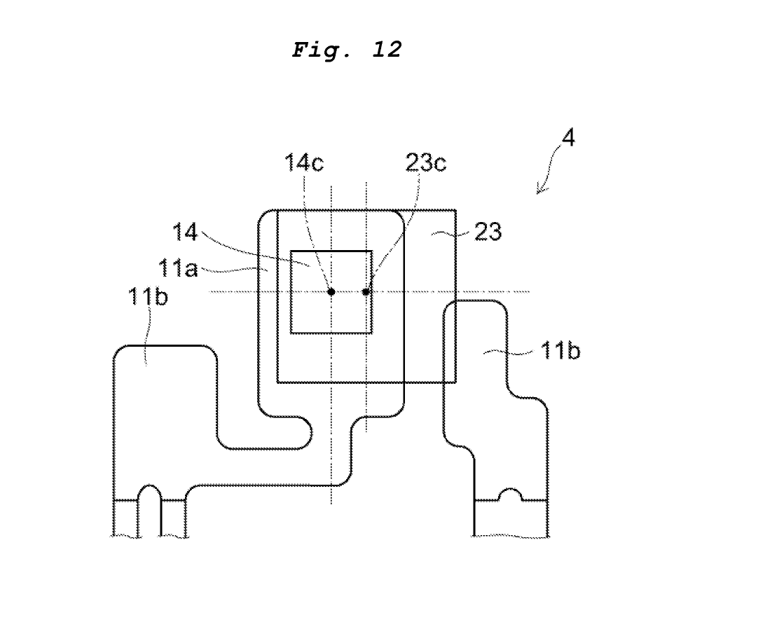

For clarity, in FIG. 11 all parts except the lead parts 11, light emitting element 14 and insulating film 23 are omitted. The same is true for FIG. 12 discussed below.

As shown in FIG. 11, for the optical coupling device 3 used in the present embodiment, when viewed from the light emitting element 14 towards the light receiving element 17 (hereinafter to be referred to as “optical axial direction”), the center 23c of the insulating film 23 coincides with the center 14c of the light emitting element 14. Also, as viewed in the optical axial direction, the center 23c of the insulating film 23 coincides with the center of the light receiving element 17 (see FIG. 1B). That is, the center 14c of the light emitting element 14, the center 23c of the insulating film 23, and the center of the light receiving element 17 are located on the same straight line.

In fabricating the previously mentioned optical coupling device 3 using the jig 100 (see FIGS. 2A and 2B), when the positional relationship between the pockets 111 and the restraining part 115 is adjusted, the positional relationship between the hole 113 and the holes 64 through the lead frame 62 is adjusted. Apart from the above configuration, the constitution, manufacturing method, operation and effects of the present embodiment are the same as those in Embodiment 1.

In the following, Embodiment 4 will be explained.

FIG. 12 is a plane view illustrating an example of the positional relationship between the leads and the insulating film in the optical coupling device in the present embodiment.

As shown in FIG. 12, for the optical coupling device 4 of the present embodiment, when viewed along the optical axis the center 23c of the insulating film 23 is offset from the center 14c of the light emitting element 14. Also, when viewed along the optical axis, the center 23c of the insulating film 23 is offset from the center of the light receiving element 17. Furthermore, when viewed along the optical axis, the center 14c of the light emitting element 14 and the center of the light receiving element 17 may or may not coincide.

The optical coupling device 4 can be fabricated by adjusting the jig 100 (see FIGS. 2A and 2B). Apart from this, the constitution, manufacturing method, operation and effects of the present embodiment are the same as those of the Embodiment 1.

As shown in Embodiment 1 through Embodiment 4, for the optical coupling device related to the embodiments, it is possible to precisely position the insulating, so that the degree of freedom of the design is high.

In the aforementioned embodiments, the insulating film 23 is bonded with the transparent resin body 22 on the side facing the light receiving element 17. Then, it is bonded with the transparent resin body 21 on the side facing the light emitting element 14. However, one may also carry out the steps of this process in reverse order. Also, the transparent resin body to be cured later may be omitted, such that only a void is formed within the device where the transparent resins would otherwise be formed. In this case, the outer layer of the molding 10 may be made of a transparent resin body instead of the opaque resin body 25. In addition, the lead parts 11 and 12 can be formed on the same lead frame, which is then folded so that the mount frames 11a and 12a of the lead parts 11 and 12 face each other.

These embodiments produce an optical coupling device with a high insulating voltage rating.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. The accompanying claims and their equivalents are intended to cover such forms or modifications as would fall within the scope and spirit of the inventions.

What is claimed is:

1. A method of fabricating an optical coupling device, the method comprising:
filling a surface of a pocket with insulating film, wherein the pocket is disposed in a stationary part of a jig device;
mounting a lead frame on a hinged part of the jig device, the lead frame having at least a first lead part attached thereto, the hinged part configured to pivot relative to the stationary part, and the first lead part comprising a first mount bed;
mounting a light receiving element on the first mount bed;
connecting a first wire to the first lead part and the light receiving element;
covering exposed surfaces of the first mount bed, the light receiving element and the wire with a first transparent resin which is not yet cured;
pivoting the hinged part of the jig device towards the stationary part of the jig device to a position, such that the first transparent resin is in contact with a first side of the insulating film and the first mount bed at a first and second contact region, respectively, and the insulating film is not in contact with the wire, the light receiving element and the first lead part; and
curing the first transparent resin.

2. The method of claim 1, further comprising
mounting a light emitting element on a second mount bed of a second lead part;
connecting a second wire to the second lead part and the light emitting element;
covering exposed surfaces of the second mount bed, the light emitting element and the wire with a second transparent resin which is not yet cured;
moving the first or second lead part to a position such that the first lead part, the second lead part and the insulating film are in a facing relationship to each other, and such that the second transparent resin is in contact with a second surface of the insulating film, wherein the second surface is on an opposite side of the insulating film relative to the first surface; and
curing the second transparent resin.

3. The method of claim 1, wherein curing the first transparent resin comprises placing the first lead part, the first transparent resin and the insulating film in a thermostatically controlled vessel having a temperature of 100 to 150° Celsius.

4. The method of claim 1, further comprising partially encapsulating the light emitting element, light receiving element, insulating film, first mount bed, second mount bed, and first and second transparent resins with a light blocking resin.

5. The method of claim 4, further comprising configuring the light blocking resin so that a portion of the first lead part and a portion of the second lead part protrude from the light blocking resin.

6. The method of claim 5, wherein the light blocking resin is a white resin or a black resin.

7. The method of claim 5, wherein pivoting the hinged part of the jig device towards the stationary part of the jig device results in the first mount bed being positioned parallel to the insulating film.

8. The method of claim 5, wherein pivoting the hinged part of the jig device towards the stationary part of the jig device results in the first mount bed not being parallel to the insulating film.

9. The method of claim 2, wherein the first lead part and the second lead part comprise a first and second plurality of leads, respectively, and wherein each of the first plurality of leads is coupled to the first mount bed, and wherein each of the second plurality of leads is coupled to the second mount bed.

10. The method of claim 2, wherein moving the first or second lead part to a position aligns the center of the light emitting element with the center of the insulating film and the center of the light receiving element, the alignment being along a single common line.
